(19) United States
(12) Patent Application Publication
(10) Pub. No.: US 2026/0089988 A1
(43) Pub. Date: Mar. 26, 2026

(54) SCHOTTKY DIODE AND METHOD FOR FABRICATING THE SAME

(71) Applicant: UNITED MICROELECTRONICS CORP., Hsin-Chu City (TW)

(72) Inventors: Kuo-Hsing Lee, Hsinchu County (TW); Sheng-Yuan Hsueh, Tainan City (TW); Ting-Hsiang Huang, Tainan City (TW); Guan-Kai Huang, Tainan City (TW); Chi-Horn Pai, Tainan City (TW)

(73) Assignee: UNITED MICROELECTRONICS CORP., Hsin-Chu City (TW)

(21) Appl. No.: 18/929,632

(22) Filed: Oct. 29, 2024

(30) Foreign Application Priority Data
Sep. 26, 2024 (TW) 113136618

(51) Int. Cl. H01L 29/66; H01L 29/06; H01L 29/872

(52) U.S. Cl. CPC H10D 8/051; H10D 8/60; H10D 62/126

(57) ABSTRACT

A method for fabricating a Schottky diode includes the steps of first forming a fin-shaped structure on a substrate, forming an epitaxial layer in the fin-shaped structure, forming a first contact plug on the epitaxial layer, and then forming a second contact plug on the fin-shaped structure adjacent to the epitaxial layer. Preferably, the first contact plug includes an ohmic contact and the second contact plug includes a Schottky contact.

### BACKGROUND OF THE INVENTION

### 1. Field of the Invention

The invention relates to a semiconductor device and method for fabricating the same, and more particularly to a Schottky diode and method for fabricating the same.

### 2. Description of the Prior Art

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### SUMMARY OF THE INVENTION

According to an embodiment of the present invention, a method for fabricating a Schottky diode includes the steps of first forming a fin-shaped structure on a substrate, forming an epitaxial layer in the fin-shaped structure, forming a first contact plug on the epitaxial layer, and then forming a second contact plug on the fin-shaped structure adjacent to the epitaxial layer. Preferably, the first contact plug includes an ohmic contact and the second contact plug includes a Schottky contact.

According to another aspect of the present invention, a Schottky diode includes a fin-shaped structure on a substrate, an epitaxial layer in the fin-shaped structure, a first contact plug on the epitaxial layer, wherein the first contact plug comprises an ohmic contact, and a second contact plug on the fin-shaped structure and adjacent to the epitaxial layer. Preferably, the second contact plug includes a Schottky contact.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate a method for fabricating a Schottky diode according to an embodiment of the present invention.

FIGS. 4-5 illustrate structural views of a Schottky diode according to an embodiment of the present invention

FIGS. 6-7 illustrate structural views of a Schottky diode according to an embodiment of the present invention

### DETAILED DESCRIPTION

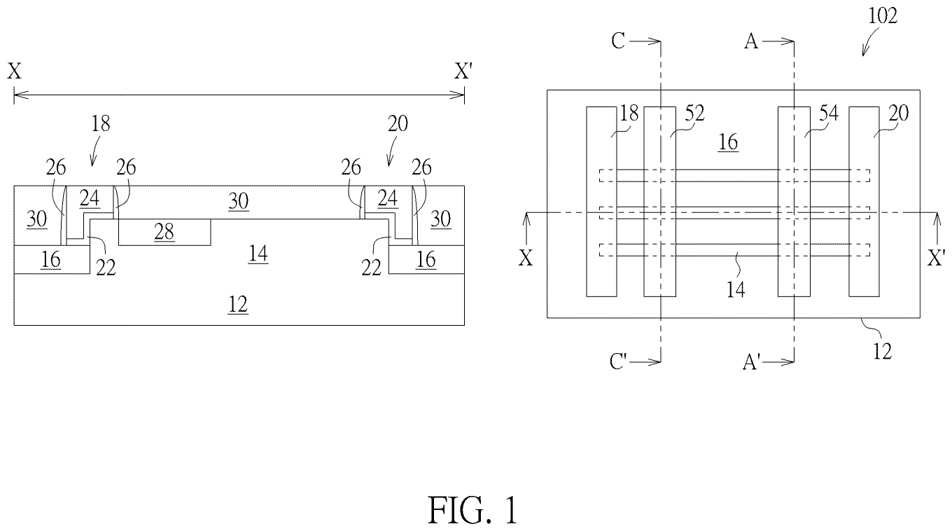

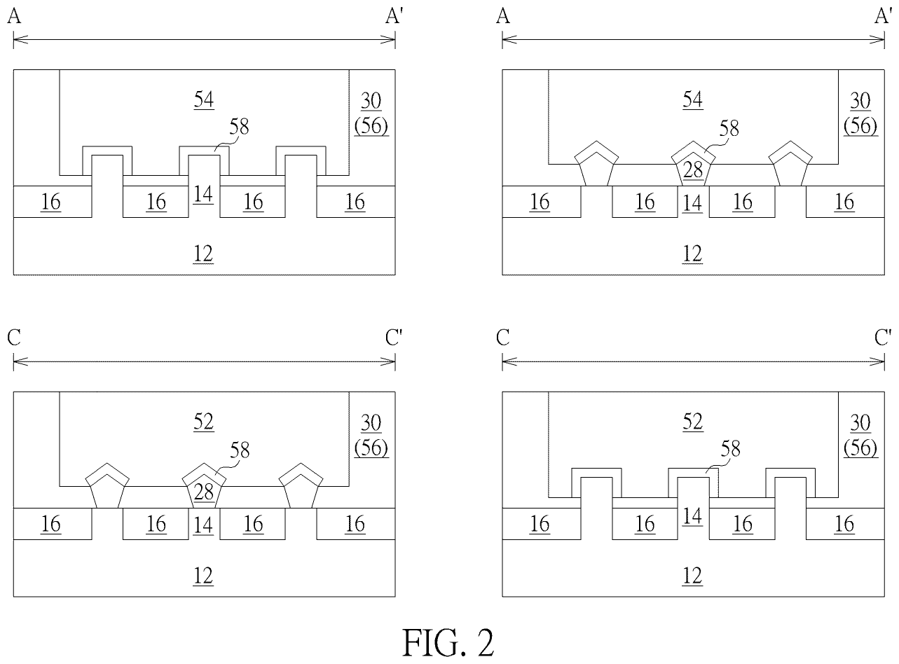

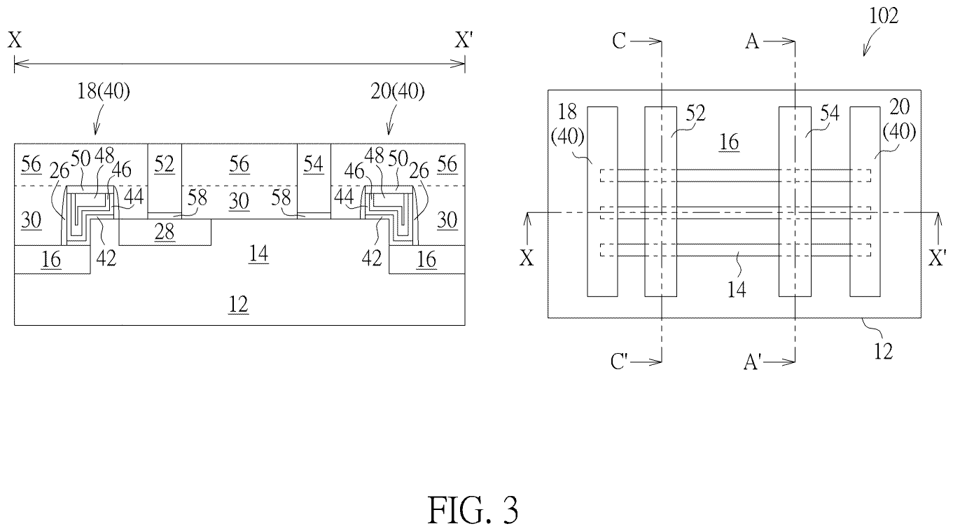

Referring to FIGS. 1-3, FIGS. 1-3 illustrate a method for fabricating a semiconductor device or more specifically a Schottky diode according to an embodiment of the present invention, in which right portion of FIG. 1 illustrates a top view for fabricating the Schottky diode according to an embodiment of the present invention, left portion of FIG. 1 illustrates a cross-section for fabricating the Schottky diode taken along the sectional line XX′ of the right portion of FIG. 1, top left portion and top right portion of FIG. 2 illustrate cross-sections for fabricating the Schottky diode taken along the sectional line AA′ of FIG. 1, bottom left portion and bottom right portion of FIG. 2 illustrate cross-sections for fabricating the Schottky diode taken along the sectional line CC′ of FIG. 1, and left portion of FIG. 3 illustrate a method for fabricating the Schottky diode after the left portion of FIG. 1.

As shown in FIGS. 1-2, a substrate 12 such as a silicon substrate or silicon-on-insulator (SOI) substrate is provided, a diode region 102 could be defined on the substrate 12 for fabricating a Schottky diode in the later process, a plurality of fin-shaped structures 14 are formed on the substrate 12, and then an insulating material such as silicon oxide is deposited in the substrate 12 to form a shallow trench isolation (STI) 16. It should be noted that even though this embodiment pertains to fabricate a non-planar device such as fin field effect transistor (FinFET), according to other embodiment of the present invention, it would also be desirable to apply the process of this embodiment to fabricate planar devices, which is also within the scope of the present invention.

According to an embodiment of the present invention, the fin-shaped structures 14 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 14 could also be obtained by first forming a patterned mask (not shown) on the substrate, 12, and through an etching process, the pattern of the patterned mask is transferred to the substrate 12 to form the fin-shaped structures. Moreover, the formation of the fin-shaped structures could be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures. These approaches for forming fin-shaped structure are all within the scope of the present invention.

Next, dummy gates or gate structures 18, 20 are formed on edges of the fin-shaped structure 14 and part of the STI 16. In this embodiment, the formation of the gate structures 18, 20 could be accomplished by sequentially depositing a gate dielectric layer 22, a gate material layer 24, and a selective hard mask (not shown) on the substrate 12, conducting a pattern transfer process by using a patterned resist (not shown) as mask to remove part of the gate material layer 24 and part of the gate dielectric layer 20, and then stripping the patterned resist to form dummy gates or gate structures 18, 20 on the substrate 12. Each of the gate structures 18, 20 preferably includes a patterned gate dielectric layer 22 and a patterned material layer 24, in which the gate dielectric layer 22 includes silicon oxide and the gate material layer 24 includes polysilicon, but not limited thereto.

Next, at least a spacer 26 is formed on sidewalls of the gate structures 18, 20 and then an epitaxial layer 28 is formed in the fin-shaped structure 14 adjacent to the gate structure 18. Preferably, the formation of the epitaxial layer 28 could be accomplished by first conducting a photo-etching process to remove part of the fin-shaped structures 14 adjacent to the gate structure 18 for forming a recess (not shown) and then conducting a selective epitaxial growth (SEG) process to form the epitaxial layer 28 in the recess. In this embodiment, each of the spacers 26 could be a single spacer or a composite spacer, each of the spacers 26 could be made of same or different materials, and the spacers 26 could be selected from the group consisting of SiO₂, SiN, SiON, and SiCN.

According to an embodiment of the present invention, the epitaxial layer 28 could also be formed to include different materials depending on the type of Schottky diode being fabricated. For instance, if the Schottky diode being fabricated were to be a p-type Schottky diode, the epitaxial layer 28 could be made of material including but not limited to for example SiGe, SiGeB, or SiGeSn. If the Schottky diode being fabricated were to be a n-type Schottky diode, the epitaxial layer 28 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layer 28 is preferred to have less or no germanium atom at all to facilitate the formation of silicide afterwards.

According to an embodiment of the present invention, it would also be desirable to form a doped region (not shown) in part or all of the epitaxial layer 28. According to another embodiment of the present invention, the doped region could also be formed insituly during the SEG process. For instance, the doped region could be formed by implanting p-type dopants during formation of a SiGe epitaxial layer, a SiGeB epitaxial layer, or a SiGeSn epitaxial layer for p-type Schottky diode, or could be formed by implanting n-type dopants during formation of a SiC epitaxial layer, SiCP epitaxial layer, or SiP epitaxial layer for n-type Schottky diode. Moreover, the dopants within the doped region could also be formed with a gradient, which is also within the scope of the present invention.

It should be noted that the epitaxial layer 28 is formed only in the fin-shaped structure 14 or substrate 12 immediately adjacent to the gate structure 18 at this stage while no epitaxial layer is formed in the fin-shaped structure 14 adjacent to the gate structure 20. Preferably, an ohmic contact will be formed between the epitaxial layer 28 and a contact plug formed afterwards while a Schottky contact will be formed between the surface of the fin-shaped structure 14 or substrate 12 adjacent to the epitaxial layer 28 and a contact plug in the later process.

Next, a selective contact etch stop layer (CESL) (not shown) could be formed on the gate structures 18, 20 and the spacers 26 and an interlayer dielectric (ILD) layer 30 is formed on the gate structures 18, 20. Next, a planarizing process such as chemical mechanical polishing (CMP) process is conducted to remove part of the ILD layer 30 for exposing the gate material layer 24 made of polysilicon so that the top surface of the gate material layer 24 is even with the top surface of the ILD layer 30.

Next, as shown in FIG. 3, a replacement metal gate (RMG) process is conducted to transform the gate structures 18, 20 into metal gates 40. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 24 and even the gate dielectric layer 22 for forming recesses (not shown) in the ILD layer 30. Next, an interfacial layer 42, a high-k dielectric layer 44, a work function metal layer 46, and a low resistance metal layer 48 are formed in the recesses, and a planarizing process such as CMP is conducted to remove part of low resistance metal layer 48, part of work function metal layer 46, and part of high-k dielectric layer 44 for forming metal gates 40. In this embodiment, each of the gate structures or metal gates 40 fabricated through high-k last process of a gate last process preferably includes an interfacial layer 42 or gate dielectric layer, a U-shaped high-k dielectric layer 44, a U-shaped work function metal layer 46, and a low resistance metal layer 48. According to an embodiment of the present invention, part of the low resistance metal layer 48, part of the work function metal layer 46, and part of the high-k dielectric layer 44 could be removed thereafter to form recesses, a hard mask 50 is formed in each of the recesses, and a planarizing process such as CMP is conducted to remove part of the hard mask 50 so that the top surfaces of the hard mask 50 and ILD layer 30 are coplanar.

In this embodiment, the high-k dielectric layer 44 is preferably selected from dielectric materials having dielectric constant (k value) larger than 4. For instance, the high-k dielectric layer 44 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 46 is formed for tuning the work function of the metal gate in accordance with the conductivity of the device. For an NMOS transistor, the work function metal layer 46 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 46 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 46 and the low resistance metal layer 48, in which the material of the barrier layer may include titanium (Ti), titanium nitride (TiN), tantalum (Ta) or tantalum nitride (TaN). Furthermore, the material of the low-resistance metal layer 48 may include copper (Cu), aluminum (Al), titanium aluminum (TiAl), cobalt tungsten phosphide (CoWP) or any combination thereof.

Next, a contact plug formation could be conducted to form contact plugs 52, 54 electrically connected to the epitaxial layer 28 and the fin-shaped structure 14 adjacent to the epitaxial layer 28. In this embodiment, the formation of contact plugs 52, 54 could be accomplished by first forming another ILD layer 56 on the ILD layer 30 and the metal gates 40, removing part of the ILD layers 30, 56 to form contact holes (not shown), and then depositing a barrier layer (not shown) and a metal layer into the contact holes. A planarizing process, such as CMP is then conducted to remove part of the metal layer, part of the barrier layer, and even part of the ILD layer 56 to form contact plugs 52, 54, in which the top surface of the contact plugs 52, 54 is even with the top surface of the ILD layer 56. In this embodiment, the ILD layers 30, 56 could include silicon oxide such as tetraethyl orthosilicate (TEOS), the barrier layer is selected from the group consisting of Ti, Ta, TiN, TaN, and WN, and the metal layer is selected from the group consisting of Al, Ti, Ta, W, Nb, Mo, and Cu.

It should be noted that during the formation of the contact plugs 52, 54, the aforementioned barrier layer and metal layer preferably react with the surface of the substrate 12 including surface of the epitaxial layer 28 and surface of the fin-shaped structure 14 to form silicides 58. Since the bottom surfaces of the contact plugs 52, 54 are disposed on the epitaxial layer 28 and silicon substrate 12 or fin-shaped structure 14 separately, the silicide 58 formed between the contact plug 52 and the epitaxial layer 28 and the silicide 58 formed between the contact plug 54 and the fin-shaped structure 14 preferably include different materials. According to an embodiment of the present invention, the silicide 58 formed between the contact plug 52 and the epitaxial layer 28 preferably includes a metal germanosilicide or more specifically titanium germanosilicide (TiSiGe) while the silicide 58 formed between the contact plug 54 and the fin-shaped structure 14 or silicon substrate 12 includes a metal silicide or more specifically titanium silicide (TiSi). This completes the fabrication of a semiconductor device according to an embodiment of the present invention.

As shown in the cross-sections on top right and bottom right portion of FIG. 2, if the Schottky diode fabricated were to be p-type Schottky diode, the substrate 12 or fin-shaped structures 14 preferably include p-well and the epitaxial layers 28 made of SiGe preferably have substantially pentagon shape cross-sections along the sectional line AA′ on top right corner, whereas the fin-shaped structures 14 made from silicon have rectangular cross-sections along the sectional line CC″ on bottom right corner. In this instance, the ohmic contact between the epitaxial layer 28 and contact plug 54 atop preferably constitute an anode while the Schottky contact between the adjacent fin-shaped structures 14 and contact plug 52 atop constitute a cathode.

Next, as shown in the cross-sections on top left and bottom left portion of FIG. 2, if the Schottky diode fabricated were to be n-type Schottky diode, the substrate 12 or fin-shaped structures 14 preferably include n-well and the epitaxial layers 28 made of SiP preferably have substantially pentagon shape cross-sections along the sectional line CC′ on bottom left corner, whereas the fin-shaped structures 14 made from silicon have rectangular cross-sections along the sectional line AA″ on top left corner. In this instance, the ohmic contact between the epitaxial layer 28 and contact plug 52 atop preferably constitute a cathode while the Schottky contact between the adjacent fin-shaped structures 14 and contact plug 54 atop constitute an anode.

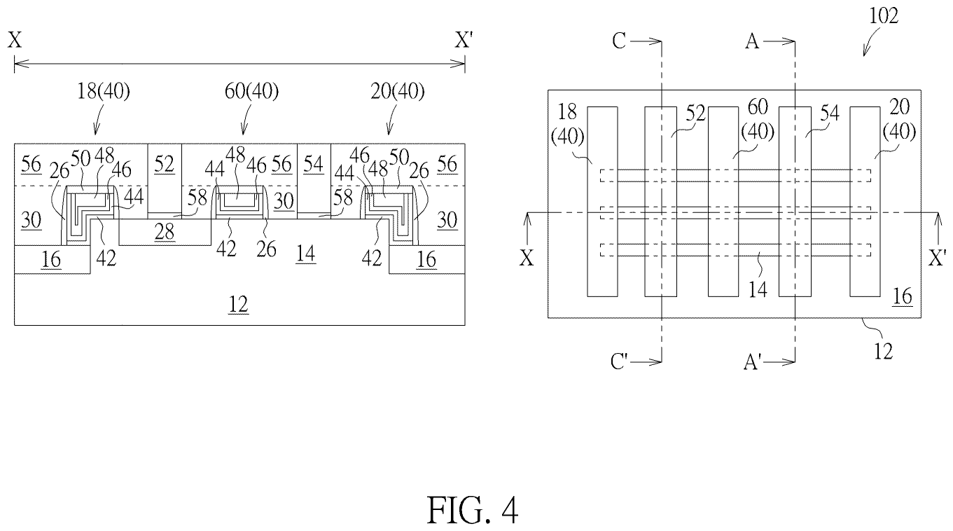

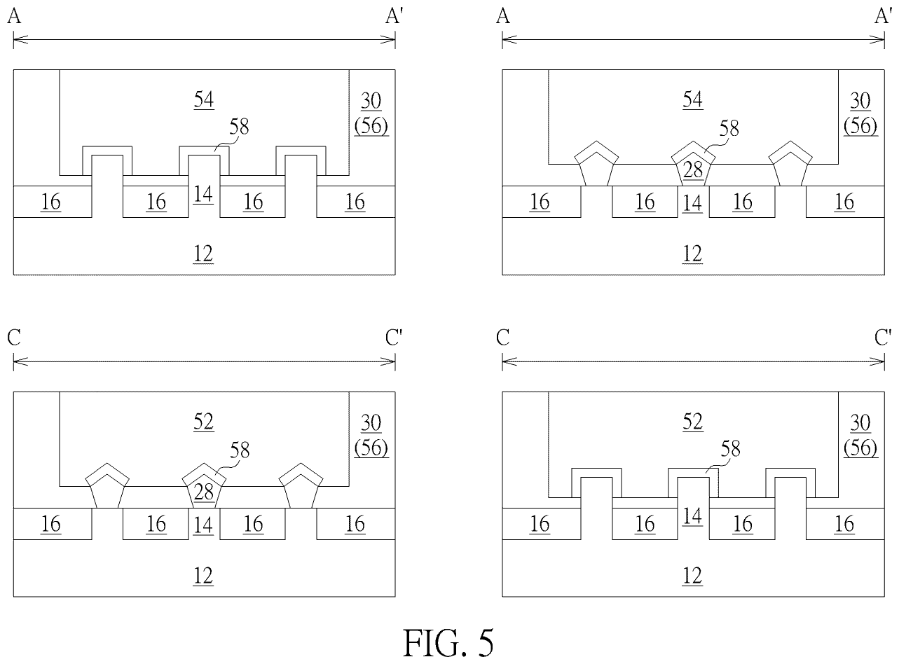

Referring to FIGS. 4-5, FIGS. 4-5 further illustrate structural views of a Schottky diode according to an embodiment of the present invention, in which right portion of FIG. 4 illustrates a top view of a Schottky diode according to an embodiment of the present invention, left portion of FIG. 4 illustrates a cross-section of the Schottky diode taken along the sectional line XX′ of the right portion of FIG. 4, top left portion and top right portion of FIG. 5 illustrate cross-sections for fabricating the Schottky diode taken along the sectional line AA′ of FIG. 4, and bottom left portion and bottom right portion of FIG. 5 illustrate cross-sections for fabricating the Schottky diode taken along the sectional line CC′ of FIG. 4.

As shown in FIGS. 4-5, in contrast to only disposing two gate structures 18, 20 adjacent to two sides of the contact plugs 52, 54, it would also be desirable to form an additional gate structure 60 between the contact plugs 52, 54 such that the epitaxial layer 28 is disposed between the gate structures 18, 60 as the edges of the epitaxial layer 28 are aligned with sidewalls of the gate structures 18, 60 or sidewalls of the spacers 26. Preferably, the gate structure 60 and the gate structures 18, 20 on two adjacent sides are made of same composition. In other words, the three gate structures 18, 20, 60 could all be fabricated through the aforementioned RMG process by transforming from polysilicon gates into metal gates 40. Similar to the aforementioned embodiments, the material of the epitaxial layer 28 could vary depending on the type of Schottky diode being fabricated. If the Schottky diode were to be a p-type Schottky diode, the epitaxial layer 28 could include SiGe, SiGeB, or SiGeSn, whereas if the Schottky diode were to be a n-type Schottky diode, the epitaxial layer 28 could include SiC, SiCP, or SiP.

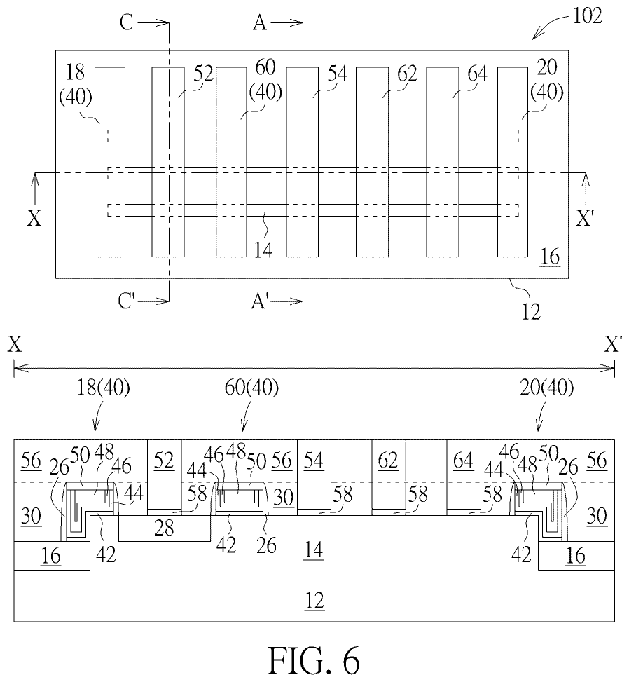

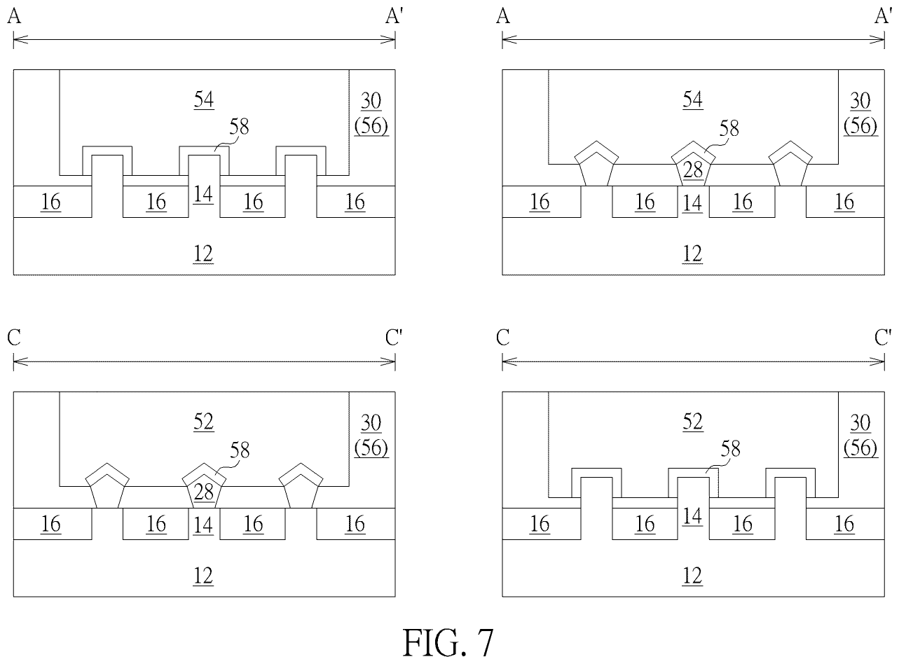

Referring to FIGS. 6-7, FIGS. 6-7 further illustrate structural views of a Schottky diode according to an embodiment of the present invention, in which top portion of FIG. 6 illustrates a top view of a Schottky diode according to an embodiment of the present invention, bottom portion of FIG. 6 illustrates a cross-section of the Schottky diode taken along the sectional line XX′ of the top portion of FIG. 6, top left portion and top right portion of FIG. 7 illustrate cross-sections for fabricating the Schottky diode taken along the sectional line AA′ of FIG. 6, and bottom left portion and bottom right portion of FIG. 7 illustrate cross-sections for fabricating the Schottky diode taken along the sectional line CC′ of FIG. 6.

As shown in FIGS. 6-7, in contrast to only disposing a single contact plug 54 between the gate structure 60 and the gate structure 20 in FIG. 4, it would also be desirable to form more than one such as three contact plugs 54, 62, 64 between the middle gate structure 60 and the right gate structure 20, in which the contact plugs 54, 62, 64 could be fabricated along with the contact plug 52 directly on top of the epitaxial layer 28 on the left. Accordingly, the four contact plugs 52, 54, 62, 64 could then have same composition as well as equal heights. By increasing the number of contact plugs between the gate structures 20, 60, it would be desirable to increase electrical current for the Schottky diode effectively.

Overall, the present invention discloses a Schottky diode and fabrication method thereof, which first forms at least two gate structures 18, 20 on the edge of the fin-shaped structure and on top of the STI, forms an epitaxial layer 28 in the fin-shaped structure immediately adjacent to the gate structure 18, and then forms a contact plug 52 on the epitaxial layer and another contact plug 54 on the fin-shaped structure. Preferably, the epitaxial layer 28 and contact plug 52 constitute an ohmic contact while the fin-shaped structure 14 or substrate 12 surface adjacent to the epitaxial layer 28 and the contact plug 54 constitute a Schottky contact. According to a preferred embodiment of the present invention, integration of an architecture having both ohmic contact and Schottky contact with fin-shaped structure architecture improves overall performance of the Schottky diode effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a Schottky diode, comprising:
forming a fin-shaped structure on a substrate;
forming an epitaxial layer in the fin-shaped structure;
forming a first contact plug on the epitaxial layer, wherein the first contact plug comprises an ohmic contact; and
forming a second contact plug on the fin-shaped structure adjacent to the epitaxial layer, wherein the second contact plug comprises a Schottky contact.

2. The method of claim 1, further comprising:
forming a shallow trench isolation (STI) around the fin-shaped structure;
forming a first gate structure on a first edge of the fin-shaped structure and the STI;
forming a second gate structure on a second edge of the fin-shaped structure and the STI;
forming the epitaxial layer adjacent to the first gate structure;
transforming the first gate structure and the second gate structure into a first metal gate and a second metal gate;
forming the first contact plug on the epitaxial layer; and
forming the second contact plug on the fin-shaped structure.

3. The method of claim 2, wherein the first gate structure is between the STI and the first contact plug.

4. The method of claim 2, wherein the second gate structure is between the STI and the second contact plug.

5. The method of claim 2, further comprising:
forming a third gate structure between the first gate structure and the second gate structure; and
transforming the first gate structure, the second gate structure, and the third gate structure into the first metal gate, the second metal gate, and a third metal gate.

6. The method of claim 5, wherein the third gate structure is between the first contact plug and the second contact plug.

7. The method of claim 5, further comprising:
forming the second contact plug, a third contact, and a fourth contact plug on the fin-shaped structure and adjacent to the epitaxial layer.

8. The method of claim 7, wherein the second contact plug, the third contact plug, and the fourth contact plug are between the second gate structure and the third gate structure.

9. A Schottky diode, comprising:
a fin-shaped structure on a substrate;
an epitaxial layer in the fin-shaped structure;
a first contact plug on the epitaxial layer, wherein the first contact plug comprises an ohmic contact; and
a second contact plug on the fin-shaped structure and adjacent to the epitaxial layer, wherein the second contact plug comprises a Schottky contact.

10. The Schottky diode of claim 9, further comprising:
a shallow trench isolation (STI) around the fin-shaped structure;
a first gate structure on a first edge of the fin-shaped structure and the STI; and
a second gate structure on a second edge of the fin-shaped structure and the STI.

11. The Schottky diode of claim 10, wherein the first gate structure is between the STI and the first contact plug.

12. The Schottky diode of claim 10, wherein the second gate structure is between the STI and the second contact plug.

13. The Schottky diode of claim 10, further comprising:
a third gate structure between the first gate structure and the second gate structure.

14. The Schottky diode of claim 13, wherein the third gate structure is between the first contact plug and the second contact plug.

15. The Schottky diode of claim 13, further comprising:
the second contact plug, a third contact, and a fourth contact plug on the fin-shaped structure and adjacent to the epitaxial layer.

16. The Schottky diode of claim 15, wherein the second contact plug, the third contact plug, and the fourth contact plug are between the second gate structure and the third gate structure.
